(19) United States
(12) Patent Application Publication
(10) Pub. No.: US 2008/0238468 A1
(43) Pub. Date: Oct. 2, 2008

(54) Integrated circuit chip and method for testing an integrated circuit chip

(75) Inventors: Andre Sturm, Essex Junction, VT (US); Thomas Vogelsang, Jericho, VT (US); Marc Walter, Munchen (DE)

Correspondence Address: POSZ LAW GROUP, PLC, 12040 SOUTH LAKES DRIVE, SUITE 101, RESTON, VA, 20191, US

(73) Assignees: Qimonda North America Corp., Cary, NC (US); Qimonda AG, Munich (DE)

(21) Appl. No.: 11/727,291

(22) Filed: Mar. 26, 2007

(51) Int. Cl. G01R 31/02

(52) U.S. Cl. 324/763

(57) ABSTRACT

In a method or apparatus such as an integrated circuit (IC) chip including a plurality of circuits for executing a plurality of testmodes, a testmode entry code specifying one of the plurality of testmodes and one of an unrestricted private testmode category and a restricted public testmode category is received. Execution of only a public testmode of the plurality of testmodes is enabled when the testmode entry code specifies the restricted public testmode category. Execution of all of the plurality of testmodes is enabled when the testmode entry code specifies the unrestricted private testmode category.

### BACKGROUND

Manufacturers of integrated circuit (IC) chips test the chips after manufacture to verify operability and performance. Particularly, an IC chip manufacturer will test the manufactured IC chips to determine if they meet a pre-package quality level referred to as Known Good Die (KGD). For example, if an IC chip is to be used in a multi-chip module, a faulty chip will lead to high replacement costs of the multi-chip module. Therefore, IC chip customers will often demand IC chips that satisfy a level of KGD.

There are several levels of KGD, each of which entails a more rigorous test plan. High KGD levels often come with a quality and reliability guarantee, such as a guarantee of function on delivery or a time period of operability. An IC chip manufacturer will often manufacture IC chips to include testmodes that are executed after manufacture in order to verify a level of KGD, as well as chip operability and performance in general. The testmodes enable different chip modes of operation, and are usually executed internally by applying a testmode entry code sequence to the IC chip.

A chip customer may wish to have access to these testmodes in order to perform its own in-house characterization of chip performance. However, providing access to these testmodes poses a significant risk to the IC chip manufacturer, such as, for example, risk of the customer using the IC chip in an unauthorized manner or gaining access to chip operating modes for which the customer did not pay. For example, due to production costs, chip manufacturers may manufacture IC chips that have multiple operating modes, and then selectively enable the operating mode of the IC chips based upon the price paid by a customer. For example, a dynamic random access memory (DRAM) chip may be manufactured to include a double-data rate (DDR) or single date rate (SDR) operating mode. Even if a chip customer pays for a lower price operating mode, the chip customer may nonetheless be able to enable the higher price operating mode if the chip customer has access to the testmodes and the test entry codes.

A chip customer or chip manufacturer may also wish to perform a test on the chip after it has been diced into a single chip and packaged. However, a packaged chip can only be accessed by its terminals. Therefore, access to the testmodes will not be feasible if the terminals are not coupled to the testmodes.

Further, when the IC chip manufacturer has developed a more cost efficient process for testing the IC chips, the testmode entry codes for activating the testmodes and the test process itself may be technology that is proprietary to the IC chip manufacturer.

### SUMMARY

A method or apparatus is proposed for testing an apparatus such as an integrated circuit (IC) chip including a plurality of testmodes. A testmode entry code specifying one of the plurality of testmodes and one of an unrestricted private testmode category and a restricted public testmode category is received; execution of only a public testmode of the plurality of testmodes is enabled when the testmode entry code specifies the restricted public testmode category; and execution of all of the plurality of testmodes is enabled when the testmode entry code specifies the unrestricted private testmode category.

### BRIEF DESCRIPTION OF THE DRAWINGS

In the accompanying figures, where like reference numerals refer to identical or functionally similar elements and which together with a detailed description set forth herein are incorporated in and form part of the specification, serve to further illustrate various exemplary embodiments and to explain various principles and advantages in accordance with this application.

FIG. 1A is a block diagram illustrating exemplary portions of an integrated circuit (IC) chip according to a first embodiment;

FIG. 1B is a flow diagram illustrating an exemplary operational method of the IC chip of the first embodiment;

FIG. 2 is a block diagram illustrating an exemplary dynamic random access memory (DRAM) chip including the exemplary portions of the first embodiment;

FIGS. 3A-3B are block diagrams illustrating exemplary portions of an IC chip according to a second embodiment and a modification to the second embodiment;

FIG. 3C is a flow diagram illustrating an exemplary operational method of the IC chip of the second embodiment; and

FIG. 4 is a block diagram of an exemplary DRAM chip including the exemplary portions of the second embodiment.

### DETAILED DESCRIPTION

The following exemplary embodiments and aspects thereof are described and illustrated in conjunction with structures and methods that are meant to be exemplary and illustrative, and not limiting in scope. In the following description, numerous specific details are set forth to provide a thorough understanding of the embodiments described in this application. In specific embodiments, circuits are shown in block diagram form in order not to obscure the embodiments described in this application in unnecessary detail. For the most part, details have been omitted inasmuch as such details are not necessary to obtain a complete understanding of the embodiments described in this application.

Referring to the figures in which like numerals refer to like parts, various exemplary embodiments of methods and apparatus for testing a chip will be discussed.

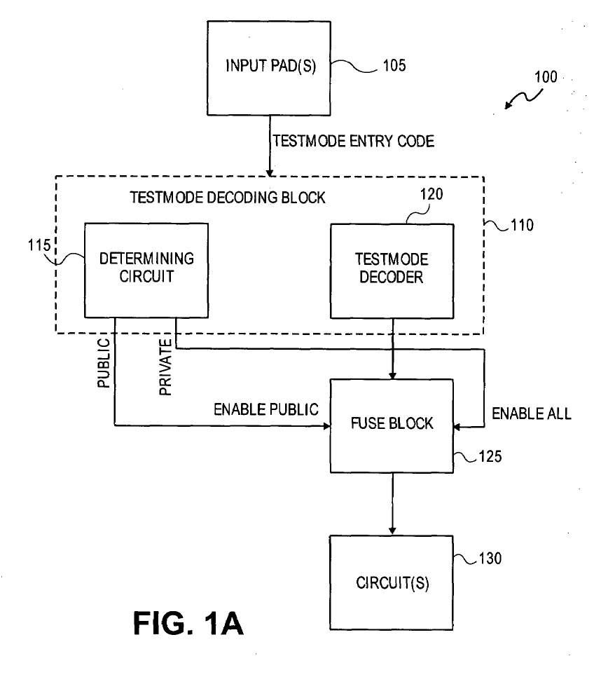

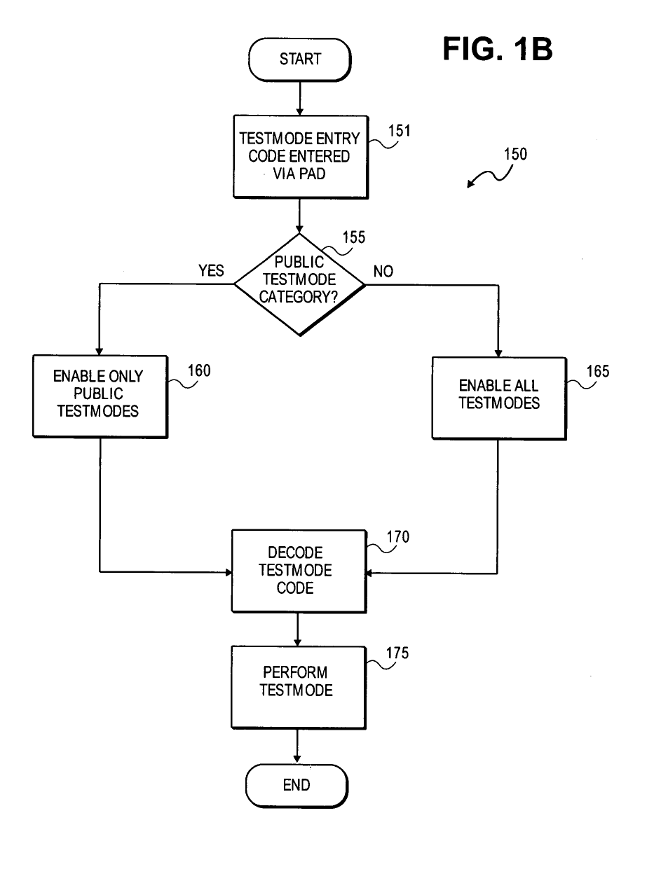

FIG. 1A is a block diagram illustrating exemplary portions of an integrated circuit (IC) chip 100 according to a first embodiment. The exemplary portions can be circuitry for permitting testing of the IC chip 100. Although the circuitry is shown separately from other portions of the IC chip 100, it should be appreciated that the circuitry along with other conventional chip circuitry is primarily internal to the IC chip 100.

As shown in FIG. 1A, the IC chip 100 includes a plurality of input pads 105 for receiving a testmode entry code specifying one of a plurality of testmodes for executing operational modes of the IC chip 100. The IC chip 100 also includes a testmode decoding block 110, a fuse block 125 and a plurality of circuits 130 for executing functions of the IC chip 100. The portions of the IC chip 100 will be discussed more fully below.

The testmode decoding block 110 is coupled to the input pads 105 to receive the testmode entry code. The testmode decoding block 110 can include a determining circuit 115 and a testmode decoder 120. The determining circuit 115 is configured to determine if the testmode entry code is associated with a private testmode category or a public testmode category. The public testmode category refers to access to unrestricted public testmodes that the manufacturer of the IC chip 100 determines not to be confidential. The private testmode category refers to access to restricted private testmodes that a manufacturer of the IC chip 100 determines to be confidential, as well as access to the unrestricted public testtnodes.

The private and public testmode categories can be implemented by, for example, assigning different categories of testmode entry codes for activating the testmodes. For example, if the IC chip 100 includes ten testmodes, and the testmode entry code is a five bit sequence, the fifth significant bit can be used to indicate the private or public testtnode category, and the first to fourth bits can be used to indicate one of the ten testmodes. The determining circuit 115 can determine which testmode category is associated with the testmode entry code by reading the fifth significant bit. The testmode decoder 120 can determine which of the circuits 130 corresponds to the specified testmode by reading the first to fourth significant bits of the testmode entry code.

The testmode decoder 120 is configured to decode the testmode entry code to determine which of the plurality of circuits 130 corresponds to the specified testmode, and to transmit an activation signal to the corresponding circuit. For example, the testmode decoder 120 can be configured to determine an address of one of the plurality testmodes specified in the testmode entry code. The testmode decoder 120 can transmit an activation signal to the circuit corresponding to the testmode to execute the testmode.

The plurality of circuits 130 is generally for executing functions of the IC chip. However, the execution of each of the plurality of circuits 130 is modified upon receiving the activation signal from the testmode decoder 120, to thereby execute a testmode of the IC chip 100. The plurality of circuits 130 can include one or more private circuits configured to execute the restricted testtnodes and one or more public circuits configured to execute the unrestricted testmodes.

The fuse block 125 couples the testmode decoder 120 to the plurality of circuits 130 so that the activation signal from the testmode decoder 120 can be transmitted to the specified one of the plurality of circuits 130. The fuse block 125 is configured to enable transmission of the activation signal to only the public circuits of the plurality of circuits 130 when the fuse block 125 is in an ENABLE PUBLIC state and to enable transmission of the activation signal to all of the plurality of circuits 130 when the fuse block 125 is in an ENABLE ALL state.

The fuse block 125 can be implemented by a plurality of so-called soft set fuses coupling the testmode decoder 120 to the plurality of circuits 130. If a soft set fuse is blown, it will decouple a connection, and if a soft set fuse is latched, it will couple the connection. The soft set fuses can be selectively blown to decouple the coupling between the testmode decoder 120 and the private circuits or latched to re-couple the coupling between the testmode decoder 120 and the private circuits depending upon whether a signal received from the determining circuit 115 places the fuse block 125 in the ENABLE PUBLIC state or the ENABLE ALL state.

As discussed above, the determining circuit 115 is configured to determine if the testmode entry code is associated with the private testmode category or the public testmode category. The determining circuit 115 can be further configured to enable transmission of the activation signal from the testmode decoder 120 to only the public circuits when the testmode entry code is determined to be associated with the public testmode category, and to enable transmission of the activation signal to all of the plurality of circuits 130 when the testmode entry code is determined to be associated with the private testmode category. Particularly, the determining circuit 115 can be coupled to the fuse block 125 to transmit an enable public signal to place the fuse block 125 in the ENABLE PUBLIC state when the testmode entry code is determined to be associated with the public testmode category and to transmit an enable all signal to place the fuse block 125 in the ENABLE ALL state when the testmode entry code is determined to be associated with the private testmode category.

For example, if the fuse block 125 is composed of a plurality of blown soft set fuses respectively connected to the plurality of circuits 130, the determining circuit 115 can send an activation signal to latch only the soft set fuses connected to the public circuits when the testmode entry code is determined to be associated with the public testmode category to place the fuse block 125 in the ENABLE PUBLIC state. The determining circuit 115 can also send an activation signal to latch all of the soft set fuses when the testmode entry code is determined to be associated with the private testmode category to place the fuse block 125 in the ENABLE ALL state. Conversely, if the fuse block 125 is composed of a plurality of latched soft set fuses respectively connected to the plurality of circuits 130, the determining circuit 115 can blow only the soft set fuses connected to the private circuits to place the fuse block 125 in the ENABLE PUBLIC state and blow none of the soft set fuses to place the place the fuse block 125 in the ENABLE ALL state.

Referring now to FIG. 1B, an exemplary operational method 150 of the IC chip 100 will be discussed with reference to the exemplary portions of the IC chip 100 shown in FIG. 1A. At 151, the IC chip 100 receives the testmode entry code via the input pads 105. The testmode entry code specifies one of the plurality of testmodes and is associated with an unrestricted private testmode category or a restricted public testmode category. The testmode entry code may be input to the IC chip 100 by, for example, a testing apparatus or a general computing device having voltage terminals coupled to the input pads 105.

At 155, the determining circuit 115 determines if the testmode entry code specifies the public testmode category. If, at 155, it is determined that the testmode entry code specifies the public testmode category, then at 160 execution of only the public testmodes is enabled. Here, the determining circuit 115 can send an enable public signal to the fuse block 125 to latch the soft set fuses coupling the testmode decoder 120 to the public circuits associated with the public testmodes and to blow the soft set fuses coupling the testmode decoder 120 to the private circuits associated with the private testmodes.

If, at 155, it is determined that the testmode entry code does not specify the public testmode category, or that the testmode entry code specifies the private testmode category, then at 160 execution of all of the plurality of testmodes is enabled. Here, the determining circuit 115 can send an enable all signal to the fuse block 125 to latch all of the soft set fuses coupling the testmode decoder 120 to the plurality of circuits 130. That is, soft set fuses coupling the testmode decoder 120 to the private circuits that were previously blown will be latched.

At 170, the testmode entry code is decoded to obtain an address of a circuit corresponding to the specified testmode, and an activation signal is transmitted to the circuit. At 175, the circuit performs the testmode. Here, the testmode decoder 120 can decode the testmode entry code to obtain the address of one of the plurality of circuits 130 corresponding to the specified testmode, and transmit an activation signal to the circuit to thereby perform the specified testmode. Because only the public testmodes are enabled when the testmode entry code specifies the restricted public testmode category, even if a customer attempted to enter a testmode entry code for a restricted private testmode, execution of the private testmode will not be performed because the one or more soft fuses coupling the testmode decoder 120 to the circuits for executing the restricted private testmodes were disabled at 165.

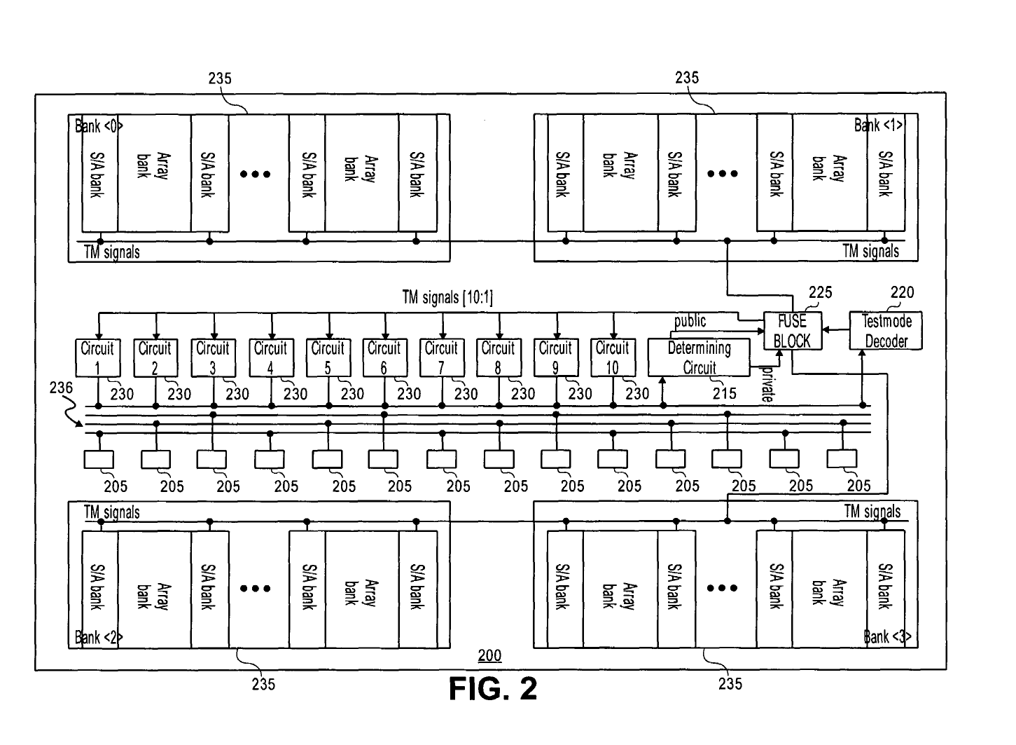

Referring to FIG. 2, an exemplary dynamic random access memory (DRAM) chip 200 including the exemplary portions shown in FIG. 1A will be discussed. The DRAM chip 200 includes a plurality of circuits 230 (ten in this example) for executing functions of the chip 200 and a plurality of input pads 205 for receiving a testmode entry code specifying one of the testmodes. The function of the plurality of circuits 230 can be modified upon receiving an activation signal to thereby perform the testmodes. The DRAM chip 200 also includes a determining circuit 215 for determining if the testmode entry code is associated with a public testmode category or a private testmode category, a testmode decoder 220 for decoding the testmode entry code, and a fuse block 225 coupling the testmode decoder 220 to the circuits 230 and to a plurality of memory banks 235. The input pads 205 can be coupled to the determining circuit 215 and the testmode decoder 220 by a data and address bus 236. It should be noted that the fuse block 225 is coupled to the circuits 230 by a plurality (ten in this example) of wires or other electrical connections, although only one is shown for ease of illustration.

The plurality of circuits 230 can include private circuits for executing the private testmodes and public circuits for executing the public testmodes. During a test operation, the testmode entry code is input to the DRAM chip 200 via the input pads 205. The determining circuit 215 determines if the testmode entry code is associated with the public testmode category or the private testmode category, and places the fuse block 225 in the ENABLE public state or the ENABLE ALL state in accordance with the determination. Simultaneously, or subsequent to, the determination, the testmode decoder 220 decodes the testmode entry code to determine which of the plurality of circuits 230 corresponds to the testmode specified in the testmode entry code and sends an activation signal to the corresponding circuit.

In the present example, if the testmode entry code is determined to be associated with the public testmode category, the determining circuit 215 will place the fuse block 225 in the ENABLE PUBLIC state in which the fuses coupling the testmode decoder 220 to the circuits for executing the private test modes are blown. If the testmode entry code is determined to be associated with the private testmode category, the determining circuit 215 will place the fuse block 225 in the in the ENABLE ALL state in which all of the fuses coupling the testmode decoder 220 to the circuits are latched.

The circuits 230 can execute testmodes for determining the speed at which data is read from and/or written to a memory cell in one of the memory banks 235, for measuring the chip power consumption, for measuring the chip leakage current, or the like, and for placing the IC chip 200 in a single or double date rate mode. However, the foregoing merely provides examples of testmodes, and is not meant to imply that there is a limitation to possible testmodes.

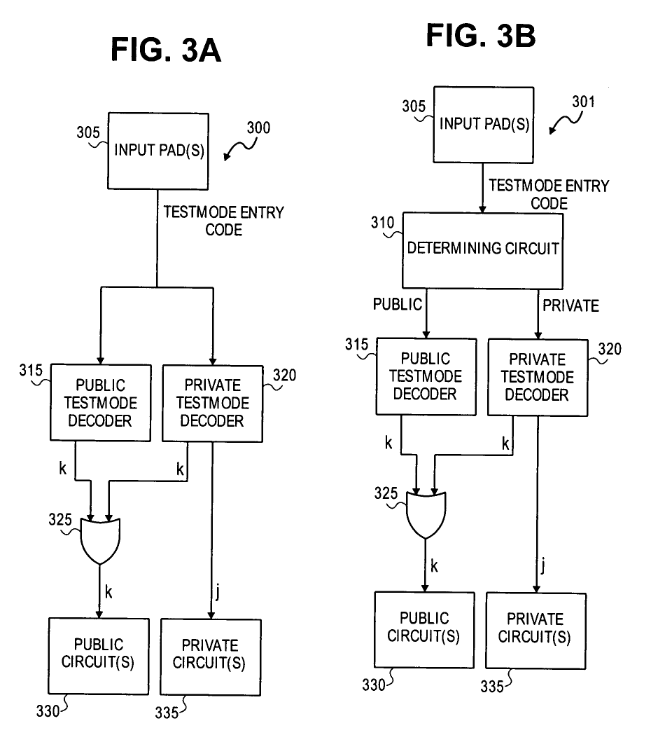

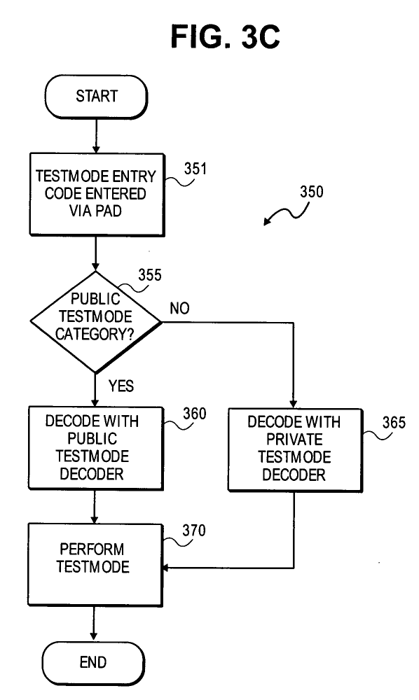

Referring to FIG. 3A, exemplary portions of an IC chip 300 according to a second embodiment will be discussed. The IC chip 300 includes a plurality of input pads 305 for receiving a testmode entry code. As discussed above, the testmode entry code specifies one of a plurality of testmodes for executing operational modes of the IC chip 300, and is associated with a public testmode category or a private testmode category. The IC chip 300 also includes a public testmode decoder 315, a private testmode decoder 320, a logical OR gate 325, and public and private circuits 330, 335 for executing the testmodes.

The public testmode decoder 315 is configured to decode an address of one of the public circuits 330 corresponding to the testmode specified by the testmode entry code, and to transmit an activation signal to the particular public circuit. As illustrated, the public testmode decoder 315 is decoupled from the private circuits 335.

The private testmode decoder 320 is configured to decode an address of one of the private circuits 335 or public circuits 330 corresponding to the testmode specified by the testmode entry code. The private testmode decoder 320 is further configured to transmit an activation signal to the particular circuit. As illustrated, the private testmode decoder 320 is coupled to both the private circuits 330 and the public circuits 335.

The public testmode decoder 315 and the private testmode decoder 320 can be configured to determine if the testmode entry code is associated with the private testmode category or the public testmode category. For example, similarly to the determining device 115 shown in FIG. 1A and discussed above, the public and private testmode decoders 315, 320 can be configured to read one or more bits of the testmode entry code specifying the private or public testmode category. Alternatively, the public testmode decoder 315 can be configured to only decode testmode entry codes associated with the public testmode category, and the private testmode decoder 320 can be configured to only decode testmode entry codes associated with the private testmode category.

The output of the logical OR gate 325 is coupled to input terminals of the public circuits 330, and the input of the logical OR gate 325 is coupled to an output terminal of the private testmode decoder 320 and to an output terminal of the public testmode decoder 315. The logical OR gate 330 is configured to receive the activation signal from the private testmode decoder 320 when the testmode entry code is associated with the private testmode category and specifies one of the public circuits, and to also receive the activation signal from the public testmode decoder 315 when the testmode entry code is associated with the public testmode category. Thus, testmode entry codes associated with the private testmode category can access both the private circuits 335 and the public circuits 330, and testmode entry codes associated with the public testmode category can access only the public circuits 330.

Referring to FIG. 3B, the IC chip 300 can alternatively be modified as shown by the IC chip 301 to include a determining circuit 310 configured to determine if the testmode entry code is associated with the private testmode category or the public testmode category, and to output the testmode entry code or a signal corresponding to the testmode entry code to the public testmode decoder 315 if the testmode entry code is associated with the public testmode category and to the private testmode decoder 320 when the testmode entry code is associated with the private testmode category.

Referring to FIG. 3C, an exemplary operational method 350 will be discussed with reference to the exemplary portions of the IC chip 300 shown in FIG. 3A. At 351, the IC chip 300 receives the testmode entry code, which specifies one of the testmodes and is associated with the unrestricted public testmode category and the restricted private testmode category, via the input pads 305. At 355, it is determined if the testmode entry code specifies the public testmode category. The determination can be done by, for example, the determining circuit 310 shown in FIG. 3B, or the public and private testmode decoders 315, 320 shown in FIG. 3A.

If, at 355, it is determined that the testmode entry code specifies the public testmode category, then at 360 the public testmode decoder 315 decodes the testmode entry code to determine the address of the public circuit corresponding to the specified testmode, and sends an activation signal to the particular circuit. That is, only the public testmodes are decoded.

If, at 355, it is determined that the testmode entry code does not specify the public testmode category, that is, the testmode entry code is uniquely associated with the private testmode category, then at 365 the private testmode decoder 315 decodes the testmode entry code to determine the address of the public circuit or private circuit corresponding to the specified testmode, and sends an activation signal to the particular circuit.

At 370, the circuit corresponding to the specified testmode receives the activation signal from either the private or public testmode decoder, and performs the testmode.

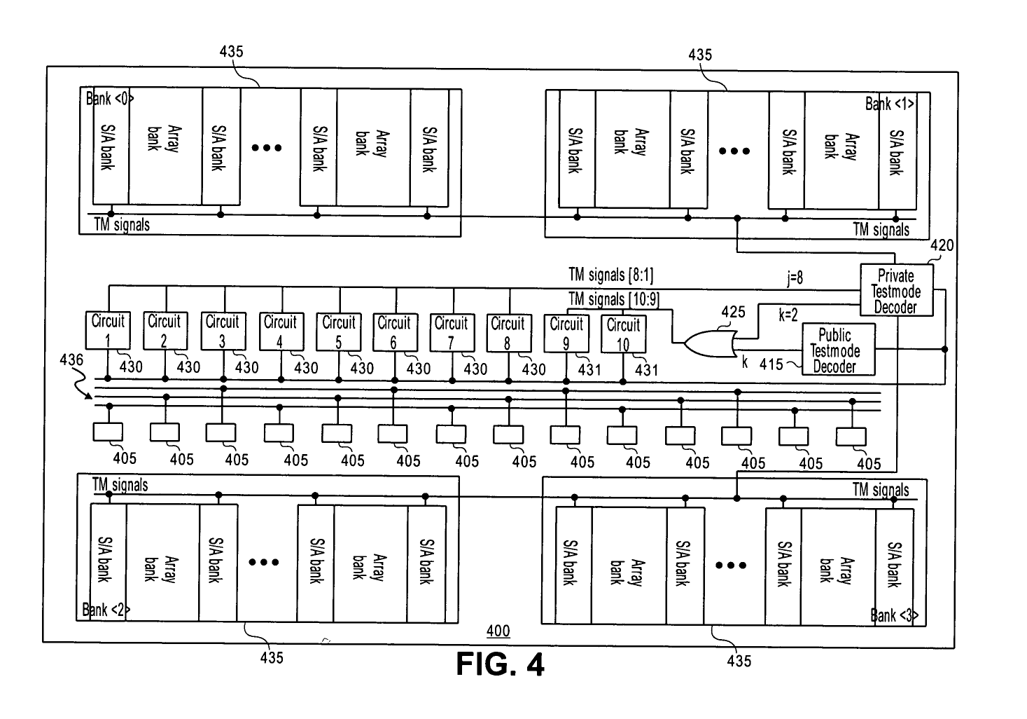

Referring to FIG. 4, an exemplary DRAM chip 400 including the exemplary portions shown in FIG. 3A will be discussed. The DRAM chip 400 includes a plurality of input pads 405 for receiving the testmode entry code, a plurality of private circuits 430 (eight in this example) for executing restricted private testmodes of the IC chip 400, and a plurality of public circuits 431 (two in this example) for executing unrestricted public testmodes of the IC chip 400.

The DRAM chip 400 also includes a public testmode decoder 415 for decoding the testmode entry code if it is associated with a restricted public testmode category, and a private testmode decoder 420 for decoding the testmode entry code if it is associated with an unrestricted private testmode category. The private testmode decoder 420 and the public testmode decoder 415 can be coupled to memory banks 435 directly or via a logical OR gate 425.

The private testmode decoder 420 is coupled to the private circuits 430. The public testmode decoder 415 and the private testmode decoder 420 are coupled to the public circuits 431 via a logical OR gate 425. Particularly, output terminals of the private testmode decoder 420 and output terminals of the public testmode decoder 415 are connected to input terminals of the logical OR gate 425, and output terminals of the logical OR gate 425 are connected to the public circuits 431.

During a test operation, the testmode entry code is input to the DRAM chip 400 via the input pads 405. The public testmode decoder 415 decodes the testmode entry code if it is associated with the public testmode category, and transmits an activation signal to one of the public circuits 431. The private testmode decoder 420 decodes the testmode entry code if it is associated with the private testmode category, and transmits an activation signal to one of the private circuits 430 or public circuits 431. Thus, testmode entry codes associated with the private testmode category can access both the private circuits 430 and public circuits 431, and testmode entry codes associated with the public testmode category can access only the public circuits 431.

The novel embodiments discussed above permit an IC chip manufacturer to grant access to a chip customer to the testmodes of the IC chip so that a customer can perform their own in-house characterization of chip performance without the risk of the customer using the IC chip in an unauthorized manner or gaining access to IC chip operating modes for which the customer did not pay. Further, the IC chip manufacturer can give the chip customer public testmode entry codes while protecting the proprietary nature of private testmode entry codes.

The foregoing description of the embodiments of the present invention is presented for purposes of illustration and description. It is not intended to be exhaustive or to limit the invention to the precise forms disclosed. Many variations and modifications of the embodiments described herein will be apparent to one of ordinary skill in the art in light of the above description. The scope of the invention is to be defined only by the claims appended hereto, as may be amended during the pendency of this application for patent, and all equivalents thereof, and by their equivalents.

Some embodiments can include a plurality of processes or steps, which can be performed in any order, unless expressly and necessarily limited to a particular order. As one of ordinary skill in the art would appreciate, other sequences of steps may be possible. Therefore, the particular order of the steps set forth in the specification should not be construed as limitations on the claims.

1. A method for testing an apparatus including a plurality of circuits for executing a plurality of testmodes, the plurality of testmodes including a public testmode and a private testmode, the method comprising:
receiving a testmode entry code specifying one of the plurality of testmodes and one of an unrestricted private testmode category and a restricted public testmode category;
enabling execution of only the public testmode when the testmode entry code specifies the restricted public testmode category; and
enabling execution of all of the plurality of testmodes when the testmode entry code specifies the unrestricted private testmode category.

2. The method of claim 1, wherein the enabling execution of only the public testmode further includes latching one or more fuses connected to one or more circuits of the plurality of circuits associated with the public testmode.

3. The method of claim 2, wherein the enabling execution of only the public testmode further includes blowing one or more fuses connected to one or more circuits of the plurality of circuits associated with the private testmode.

4. The method of claim 1, wherein the enabling execution of only the public testmode further includes:
decoding the testmode entry code with a public testmode decoder to obtain an address of a circuit of the plurality of circuits corresponding to the specified one of the plurality of testmodes; and
transmitting an activation signal to the circuit when the testmode entry code specifies the restricted public testmode category, the public testmode decoder being decoupled from one or more circuits of the plurality of circuits associated with the private testmode.

5. The method of claim 1, wherein the enabling execution of all of the plurality of testmodes further includes:
decoding the testmode entry code with a private testmode decoder to obtain an address of a circuit of the plurality of circuits corresponding to the specified one of the plurality of testmodes; and
transmitting an activation signal to the circuit when the testmode entry code specifies the unrestricted private testmode category, the private testmode decoder being coupled to all of the plurality of circuits.

6. A method for testing an apparatus including a plurality of circuits for executing a plurality of testmodes, the plurality of testmodes includes a public testmode and a private testmode, the method comprising:
receiving a testmode entry code specifying one of the plurality of circuits, and one of a private testmode category and a public testmode category;
decoding the testmode entry code with a public testmode decoder coupled only to one or more circuits of the plurality of circuits associated with the public testmode when the testmode entry code specifies the public testmode category; and
transmitting an activation signal to the specified one of the plurality of circuits.

7. The method of claim 6, further comprising decoding the testmode entry code with a private testmode decoder coupled to all of the plurality of circuits when the testmode entry code specifies the private testmode category.

8. The method of claim 6, further comprising determining if the testmode entry code specifies the private testmode category or the public testmode category.

9. An integrated circuit chip comprising:
at least one public circuit configured to execute one or more unrestricted testmodes;
at least one private circuit configured to execute one or more restricted testmodes;
a decoder configured to decode a testmode entry code specifying one of the at least one public circuit and the at least one private circuit, and to transmit an activation signal to the specified one of the at least one public circuit and the at least one private circuit; and
a fuse block coupling the decoder to the at least one public circuit and the at least one private circuit, the fuse block configured to enable transmission of the activation signal to only the at least one public circuit when the fuse block is in an ENABLE PUBLIC state in accordance with the testmode entry code.

10. The integrated circuit chip according to claim 9, wherein the fuse block is further configured to enable transmission of the activation signal to the at least one private circuit and the at least one public circuit when the fuse block is in an ENABLE ALL state in accordance with the testmode entry code.

11. The integrated circuit chip according to according to claim 9, further comprising a determining device configured to determine if the testmode entry code is associated with an unrestricted category or a restricted category, to place the fuse block in the ENABLE PUBLIC state when the testmode entry code is determined to be associated with the restricted category, and to place the fuse block in the ENABLE ALL state when the testmode entry code is determined to be associated with the unrestricted category.

12. The integrated circuit chip according to claim 9, wherein the fuse block includes one or more soft set fuses coupling the decoder to the at least one private circuit.

13. The integrated circuit chip according to claim 9, wherein:
the fuse block is further configured to enable transmission of the activation signal to the at least one private circuit and the at least one public circuit when the fuse block is in an ENABLE ALL state in accordance with the testmode entry code; and
the fuse block includes a plurality of soft set fuses coupled to the at least one private circuit, the plurality of soft set fuses configured to be blown when the fuse block is in the ENABLE PUBLIC state and to be latched when the fuse block is in the ENABLE ALL state.

14. The integrated circuit chip according to claim 9, further comprising:
a plurality of input pads for receiving the testmode entry code; and
a data and address bus coupling the plurality of input pads to the decoder.

15. The integrated circuit chip according to claim 9, further comprising a plurality of memory banks for storing data coupled to the fuse block.

16. An integrated circuit chip comprising:
an input pad for receiving a testmode entry code specifying one of a plurality of testmodes executing operational modes of the integrated circuit chip;
a plurality of circuits coupled to the determining device, the plurality of circuits configured to execute the plurality of testmodes, the plurality of circuits including public circuits and private circuits; and
a public testmode decoder coupled to the input pad, the public testmode decoder configured to decode an address of one of the public circuits corresponding to the one of the plurality of testmodes specified by the testmode entry code and to transmit an activation signal to the one of the public circuits when the testmode entry code is associated with a public testmode category, wherein the public testmode decoder is decoupled from the private circuits.

17. The integrated circuit chip according to claim 16, further comprising:
a private testmode decoder configured to decode an address of one of the plurality of circuits corresponding to the one of the plurality of testmodes specified by the testmode entry code and transmit an activation signal to the one of the plurality of circuits when the testmode entry code is associated with a private testmode category, wherein the private testmode decoder is coupled to all of the plurality of circuits.

18. The integrated circuit chip according to claim 17, further comprising:
a logical OR gate coupled to input terminals of the public circuits and output terminals of the private testmode decoder and the public testmode decoder.

19. The integrated circuit chip according to claim 18, wherein the logical OR gate is configured to receive the activation signal from the private testmode decoder when the testmode entry code is associated with the private testmode category and specifies one of the public circuits.

20. The integrated circuit chip according to claim 16, further comprising a determining device coupled to the input pad, the determining device configured to determine if the testmode entry code is associated with a private testmode category or the public testmode category.

21. The integrated circuit chip according to claim 20, further comprising a data and address bus coupling the input pad to the determining circuit.

22. An integrated circuit chip comprising:
a plurality of circuits for executing a plurality of testmodes of the integrated circuit chip, the plurality of testmodes including private testmodes and public testmodes;
means for determining if a testmode entry code specifying one of the plurality of testmodes is associated with a private testmode category or a public testmode category;
means for activating one of the plurality of circuits corresponding to the one of the plurality of testmodes specified by the testmode entry code; and
means for enabling execution of only the public testmodes when the testmode entry code is determined to be associated with the public testmode category.

23. The integrated circuit chip of claim 22, wherein the means for enabling execution of only the public testmodes further includes public testmode decoding means for decoding the testmode entry code to obtain an address of the circuit corresponding to the one of the plurality of testmodes specified by the testmode entry code and transmitting an activation signal to the circuit when the testmode entry code is determined to be associated with the public testmode category, the public testmode decoding means being decoupled from circuits associated with the private testmodes.

24. The integrated circuit chip of claim 22, further comprising means for enabling execution of the public testmodes and the private testmodes when the testmode entry code is determined to be associated with the private testmode category.

25. The integrated circuit chip of claim 24, wherein the means for enabling execution of the public testmodes and the private testmodes further includes private testmode decoding means for decoding the testmode entry code to obtain an address of the circuit corresponding to the one of the plurality of testmodes specified by the testmode entry code and transmitting an activation signal to the circuit when the testmode entry code is determined to be associated with the private testmode category, the private testmode decoding means being coupled to all of the plurality of circuits.
